(19) United States
(12) Patent Application Publication
(10) Pub. No.: US 2012/0154363 A1
(43) Pub. Date: Jun. 21, 2012

(54) LINE FILTER AND FLAT PANEL DISPLAY DEVICE USING THE SAME

(75) Inventors: Deuk Hoon KIM, Incheon (KR); Jae Sun WON, Suwon (KR); Young Min LEE, Suwon (KR); Sang Joon SEO, Suwon (KR); Tae Shik KIM, Yongin (KR)

(73) Assignee: SAMSUNG ELECTRO-MECHANICS CO., LTD.

(21) Appl. No.: 13/228,939

(22) Filed: Sep. 9, 2011

(30) Foreign Application Priority Data
Dec. 16, 2010 (KR) 10-2010-0129146

(51) Int. Cl. G09G 5/00; H03H 7/01

(52) U.S. Cl. 345/211; 333/185

(57) ABSTRACT

There are provided a line filter and a flat panel display device using the same. The line filter includes: first and second bobbins each including a pipe shaped body part having a through-hole formed therein and a flange part protruding outwardly from both ends of the body part; a core inserted into the through-hole to thereby form a magnetic path; and a coil part including coils, each wound in the first and second bobbins, wherein the coil wound in one of the first and second bobbins is wound clockwise and the coil wound in the other thereof is wound counterclockwise.

### CROSS-REFERENCE TO RELATED APPLICATIONS

This application claims the priority of Korean Patent Application No. 10-2010-0129146 filed on Dec. 16, 2010, in the Korean Intellectual Property Office, the disclosure of which is incorporated herein by reference.

### BACKGROUND OF THE INVENTION

1. Field of the Invention

The present invention relates to a line filter and a flat panel display device using the same.

2. Description of the Related Art

A switching mode power supply (SMPS) is generally used as a power supply in electric and electronic devices such as a display device, a printer, or the like.

The SMPS, a module type power supply, converts electricity supplied from the outside so as to be appropriate for various electric and electronic devices such as a computer, a television (TV), a video cassette recorder (VCR), a switchboard, a wireless communications device, and the like, and serves to control triggering for a high frequency greater than a commercial frequency, and alleviate impacts using semiconductor switching characteristics.

This SMPS generally includes a line filter in order to improve electromagnetic interference (EMI). The line filter is a coil component in which a coil is wound around a core. As a line filter, included in the SMPS according to the related art, a toroidal line filter has mainly been used.

EMI may be divided into conducted emissions and radiated emissions, each of which is again classified into differential mode EMI and common mode EMI.

Each common mode line filter (for example, a choke coil filter) needs to be used in a live line and a neutral line of power input lines in order to remove common mode EMI, and at least one differential mode line filter (for example, a choke coil filter) needs to be separately used in order to remove differential mode EMI.

However, a volume of the SMPS may be increased due to the use of a choke coil filter for removing the above-mentioned EMI, such that customer demand for slimness and lightness is not satisfied.

Further, in the case of the line filter (for example, a choke coil filter) according to the related art, since an insulating bobbin is assembled with a toroidal core, and two coils are wound in the bobbin in opposite directions, automated production is difficult, such that production speed is low, thereby causing an increase in manufacturing costs.

Meanwhile, in the area of flat panel displays (FPD), research into technology for the slimming of a product overall has been actively conducted. Therefore, various flat panel display devices such as a liquid crystal display (LCD) , a plasma display panel (PDP), an organic light emitting diode (OLED), and the like, have been developed.

In accordance with the slimness of the display device, a recent display device has been formed so that a back cover and the SMPS have a significantly narrow interval therebetween. Therefore, the line filter mounted in the SMPS is configured such that a coil thereof is disposed decidedly adjacent to the back cover of the display device.

According to the related art, the toroidal line filter is mainly used as described above. In this case, a leakage flux generated in the line filter may cause interference with the back cover, thereby creating vibrations therein. Therefore, noise may be generated in the display device.

### SUMMARY OF THE INVENTION

An aspect of the present invention provides an integrated line filter capable of filtering both differential mode electromagnetic interference (EMI) and common mode EMI.

Another aspect of the present invention provides a line filter having a structure in which a coil is wound in parallel with a printed circuit board.

Another aspect of the present invention provides a flat panel display device capable of significantly reducing an influence of magnetic flux, generated by a line filter, on the display device.

According to an aspect of the present invention, there is provided a line filter including: first and second bobbins each including a pipe shaped body part having a through-hole formed therein and a flange part protruding outwardly from both ends of the body part; a core inserted into the through-hole to thereby forma magnetic path; and a coil part including coils, each wound in the first and second bobbins, wherein a coil wound in one of the first and second bobbins is wound clockwise and a coil wound in the other thereof is wound counterclockwise.

Each of the first and second bobbins may include a fitting coupling part coupling the first and second bobbins to each other so that the flange part of the first bobbin and the flange part of the second bobbin contact each other.

The fitting coupling part may include at least one fitting protrusion; and at least one fitting groove having at least one fitting protrusion fitted thereinto.

The fitting coupling part maybe formed on each surface on which the flange parts of the first bobbin and the flange parts of the second bobbin contact each other.

The first and second bobbins may be coupled with each other while the at least one fitting protrusion included in one of the first and second bobbins is fitted into the at least one fitting groove included in the other thereof.

Each of the first and second bobbins may include at least two external connection terminals.

Any one of the first and second bobbins may further include an auxiliary terminal having the same shape as that of the external connection terminal.

The first and second bobbins may be distinguished from each other by the auxiliary terminal.

The external connection terminal may include: an extension part extended from a first flange part formed at one end of the body part; and a coupling part bent from the extension part and extended in a formation direction of a second flange part from a first flange part.

After the coils are wound in the first and second bobbins, the external connection terminal may be bent to thereby be divided into the extension part and the coupling part.

When the line filter is mounted on an external substrate, the external connection terminal may include a protrusion part protruding outwardly from the coupling part, the protrusion part setting a mounting height of the line filter.

Each of the first and second bobbins may include at least one rib protruding from an outer surface of the flange part, the at least one rib reinforcing rigidity of the flange part.

The core may be a UU shaped core or a UI shaped core.

According to another embodiment of the present invention, there is provided a line filter including: first and second bobbins each including a pipe shaped body part having a through-hole formed therein and a flange part protruding outwardly from both ends of the body part; a core inserted into the through-holes of the first and second bobbins to thereby form a magnetic path; a coil part including coils, each wound in the first and second bobbins; and a plurality of external connection terminals coupled to the first and second bobbins and electrically connected to the coils, wherein one of the first and second bobbins further includes an auxiliary terminal having the same shape as that of the external connection terminal.

The first and second bobbins may be coupled with each other so that flange parts of the first bobbin and flange parts of the second bobbin contact each other, such that they are formed integrally with each other.

The line filter may further include fitting coupling parts each formed on a surface on which the flange parts of the first bobbin and the flange parts of the second bobbin contact each other to thereby couple the first and second bobbins to each other.

The coil wound in one of the first and second bobbins may be wound clockwise and the coil wound in the other thereof may be wound counterclockwise.

According to another embodiment of the present invention, there is provided a flat panel display device including: a switching mode power supply including at least one line filter as described above mounted on a substrate thereof; a display panel receiving power from the switching mode power supply; and covers protecting the display panel and the switching mode power supply.

The coils of the at least one line filter may be wound in the first and second bobbins so as to be parallel with the substrate of the switching mode power supply.

The substrate of the switching mode power supply may include a through-hole formed therein, and the line filter may be mounted on the substrate while being received in the through-hole.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view showing a line filter according to an embodiment of the present invention;

FIG. 2 is a perspective view showing a bobbin part of the line filter shown in FIG. 1;

FIG. 3 is a perspective view showing a lower part of a bobbin part shown in FIG. 2;

FIG. 4 is a perspective view schematically showing a line filter according to another embodiment of the present invention;

FIG. 5 is a perspective view showing a bobbin part of the line filter shown in FIG. 4;

FIG. 6 is a perspective view showing a state in which the line filter of FIG. 4 is mounted on a substrate;

FIG. 7 is a perspective view showing a method of manufacturing the line filter of FIG. 4;

FIG. 8 is a circuit diagram of the line filter shown in FIGS. 1 and 4;

FIG. 9 is a graph showing electrical characteristics of the line filter shown in FIGS. 1 and 4; and

FIG. 10 is an exploded perspective view schematically showing a flat panel display device according to an embodiment of the present invention.

### DETAILED DESCRIPTION OF THE EMBODIMENT

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention. Therefore, the configurations described in the embodiments and drawings of the present invention are merely the most preferable embodiments but do not represent all of the technical spirit of the present invention. Thus, the present invention should be construed as including all the changes, equivalents, and substitutions included in the spirit and scope of the present invention at the time of the filing of this application.

Hereinafter, embodiments of the present invention will be described in detail with reference to the accompanying drawings. At this time, it is noted that like reference numerals denote like elements in appreciating the drawings. Moreover, detailed descriptions related to well-known functions or configurations will be ruled out in order not to unnecessarily obscure the subject matter of the present invention. Based on the same reason, it is to be noted that some components shown in the drawings are exaggerated, omitted or schematically illustrated, and the size of each component may not exactly reflect its real size.

Hereinafter, embodiments of the present invention will be described in detail with reference to the accompanying drawings.

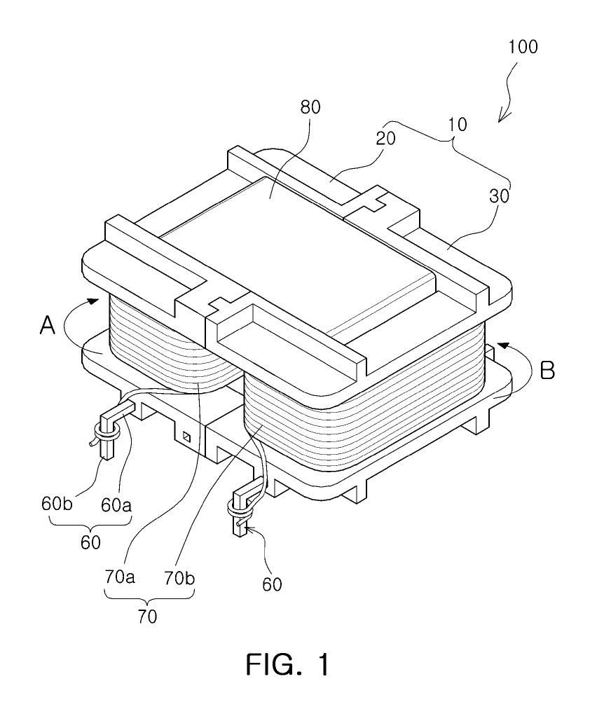

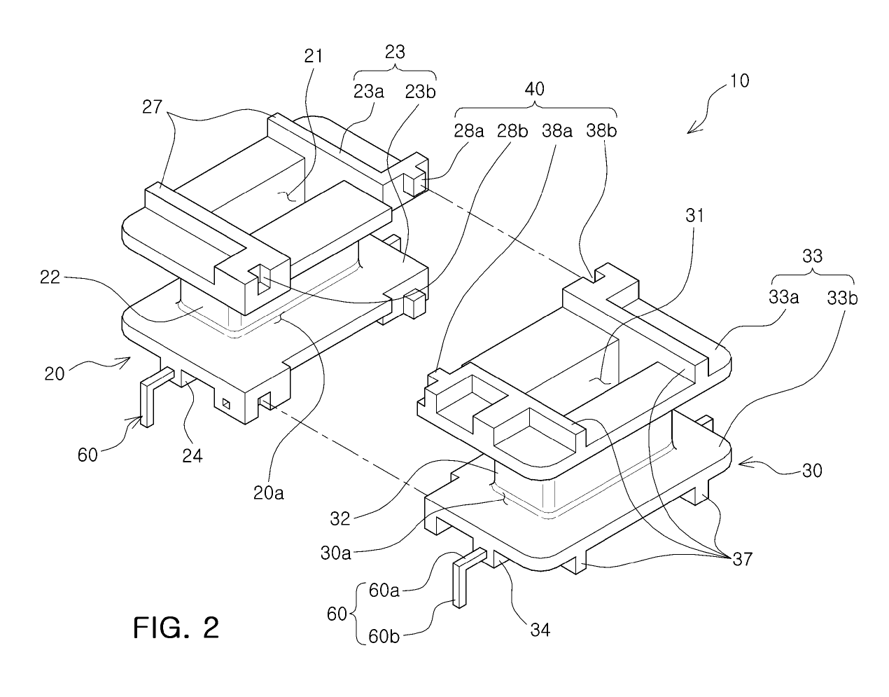

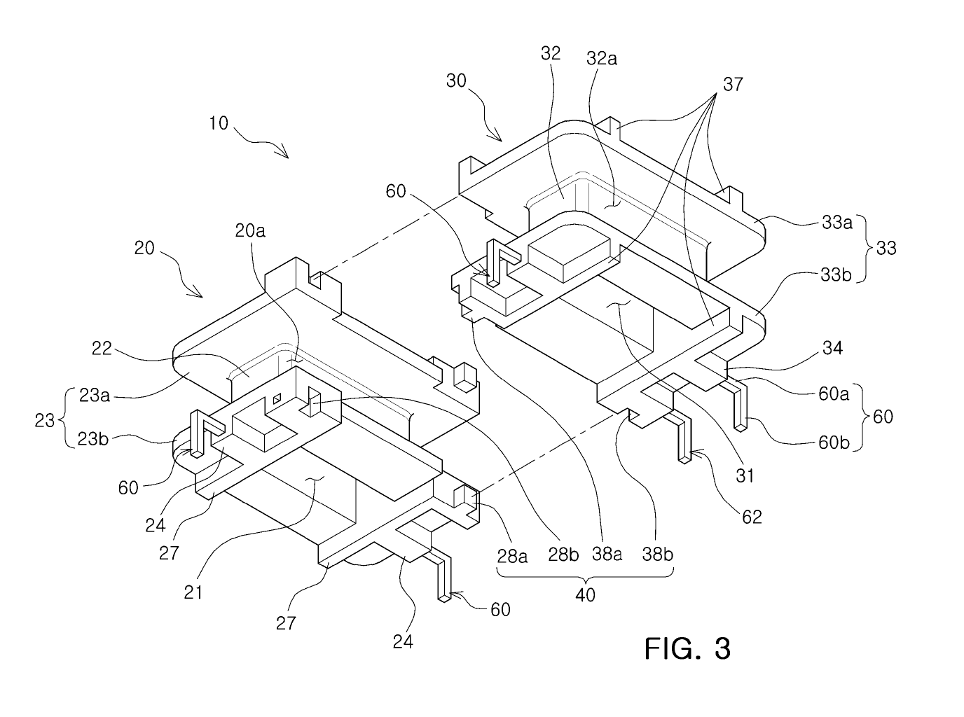

FIG. 1 is a perspective view schematically showing a line filter according to an embodiment of the present invention; and FIG. 2 is a perspective view showing a bobbin part of the line filter shown in FIG. 1. FIG. 3 is a perspective view showing a lower part of a bobbin part shown in FIG. 2.

Referring to FIGS. 1 through 3, a line filter 100 according to an embodiment of the present invention may include a bobbin part 10, a coil part 70, and a core 80.

The bobbin part 10 may include a first bobbin 20 and a second bobbin 30.

The first bobbin 20 may include a pipe shaped body part 22 having a through-hole 21 formed at the center of an inner portion thereof, a flange part 23 vertically extended from both ends of the body part 22 in an outer diameter direction thereof, external connection terminals 60 for electrical and physical connection to the outside, and a fitting coupling part 40, as shown in FIG. 2.

The through-hole 21 formed in the inner portion of the body part 22 is used as a path into which a portion of the core 80 to be described below is inserted. The present embodiment describes a case in which the through-hole 21 has a rectangular cross section by way of example. The above-mentioned cross sectional shape corresponds to a shape of the core 80 inserted into the through-hole 21. In the first bobbin 20 according to the embodiment of the present embodiment, the through-hole 21 is not limited to having the above-mentioned shape but may have various shapes corresponding to shapes of the core 80 inserted thereinto.

The flange part 23 is divided into a first flange part 23a and a second flange part 23b according to a formation position thereof. In addition, a space formed between an outer peripheral surface of the body part 22 and the first and second flange parts 23a and 23b is used as a winding part 20a in which a coil 70 to be described below is wound. Therefore, the flange part 23 serves to protect the coil 70 from the outside and secure an insulation property between the outside and the coil 70, simultaneously with supporting the coil 70 wound in the winding part 20a at both sides thereof.

The second flange part 23b of the first bobbin 20 may include a terminal connection part 24 formed on one side thereof, wherein the terminal connection part 24 includes the external connection terminals 60 connected thereto. The terminal connection part 24 according to the present embodiment protrudes downwardly from the second flange part 23b.

The external connection terminals 60 are connected to the terminal connection part 24 so that they protrude from the terminal connection part 24 in an outer diameter and a downward direction of the body part 22. Particularly, the external connection terminals 60 according to the present embodiment may include an extension part 60a protruding parallel with the second flange part 23b and a coupling part 60b bent (for example, downwardly) from the extension part 60a. Here, the coupling part 60b is coupled to a substrate (for example, a substrate of a switching mode power supply (SMPS)), or the like, to thereby be physically and electrically connected thereto.

As shown in FIG. 3, the first bobbin 20 according to the present embodiment may include two external connection terminals 60 disposed in an opposite directions to each other.

Therefore, a primary coil 70a wound in the winding part 20a has both ends thereof respectively connected to two external connection terminals 60 to thereby be electrically connected thereto.

In addition, the line filter 100 according to the present embodiment may include ribs 27 formed on outer surface of the flange part 23. The ribs 27 have a protrusion shape protruding from the outer surface of the flange part 23 to the outside and reinforce rigidity of the flange part 23 to thereby prevent the flange part 23 from being bent.

In addition, when a core 80 to be described below is inserted into the first and second bobbins 20 and 30, the ribs 27 according to the present embodiment serve to fix movements thereof. To this end, the ribs 27 protrude in a shape corresponding to that of the core 80. Therefore, the bobbins 20 and 30 and the core 80 are closely coupled with each other, whereby close adhesion therebetween may be increased.

Meanwhile, although the present embodiment describes a case in which the ribs 27 are formed on both of the outer surfaces of two flange parts 23 included in the first bobbin 20 by way of example, the present invention is not limited thereto. The ribs 27 may only be selectively formed on any of the outer surfaces as needed.

The first bobbin 20 according to the present embodiment is coupled to a second bobbin 30 to be described below and is formed integrally with the second bobbin 30. To this end, the first bobbin 20 includes a fitting coupling part 40 formed on an outer peripheral edge of the flange part 23.

The fitting coupling part 40 includes a fitting protrusion 28a and a fitting groove 28b.

The fitting protrusion 28a and the fitting groove 28b according to the present embodiment may be formed at a side at which the first and second bobbins 20 and 30 contact each other on the outer peripheral edge of the flange part 23. Therefore, the fitting coupling part 40 is provided in the second bobbin 30 as well as in the first bobbin 20.

This fitting coupling part 40 will be described in detail in a description of a second bobbin 30 to be described below.

The second bobbin 30 has a similar shape to that of the first bobbin 20 with the exception of a configuration of external connection terminals 60.

Therefore, hereinafter, a detailed description of the same configuration of the first bobbin 20 will be omitted, and a configuration of the external connection terminals 60 different from those of the first bobbin 20 will be described in more detail.

The second bobbin 30 according to the present embodiment includes at least three external connection terminals 60, each of which includes an extension part 60a and a coupling part 60b, similar to the external connection terminal 60 of the first bobbin 20.

In addition, only two of three external connection terminals 60 of the second bobbin 30 are connected to a secondary coil 70a wound in a winding part 30a. Therefore, the above-mentioned two external connection terminals 60 are disposed in opposite directions to each other, similar to the external connection terminals 60 of the first bobbin 20. Therefore, a coil 70b wound in the winding part 30a has both ends respectively connected to two external connection terminals 60 to thereby be electrically connected thereto.

In addition, a remaining single external connection terminal 62 (hereinafter, referred to as an auxiliary terminal) is provided in order to easily distinguish between the first and second bobbins 20 and 30.

The first and second bobbins 20 and 30 according to the present embodiment have a substantially significantly similar shape to each other. Therefore, when the second bobbin 30 does not include the auxiliary terminal 62, it has the substantially same shape as that of the first bobbin 20. Therefore, it is difficult to easily distinguish between the first and second bobbins 20 and 30 with the naked eye.

Therefore, in the line filter 100 according to the present embodiment, a separate auxiliary terminal 62 is formed in the second bobbin 30 in order to easily distinguish between the first and second bobbins 20 and 30.

The second bobbin 30 includes the auxiliary terminal 62 as described above, such that the first and second bobbins and 30 are clearly distinguishable from each other. Therefore, the first bobbin 20 may be prevented from being mistaken for the second bobbin 30, such that the coil 70 is wound in an incorrect direction, or the like, may be prevented.

Further, in the line filter 100 according to the present embodiment, when the first and second bobbins 20 and 30 are coupled with each other, the respective amounts of external connection terminals 60 disposed at both sides of the line filter 100 are different due to the auxiliary terminal 62. That is, when two external connection terminals 60 are disposed at any one side of the line filter, three external connection terminals 60 and 62 are disposed at the other side thereof.

Therefore, even during a process in which the line filter 100 according to the present embodiment is mounted on a substrate (for example, a substrate of the SMPS) , a direction in which the line filter 100 is mounted may be easily recognized based on a form in which the external connection terminals 60 are disposed, whereby an amount of time required for mounting the line filter may be significantly reduced.

Meanwhile, referring to FIG. 3, the present embodiment describes a case in which the auxiliary terminal 62 is disposed at the same side as a side at which any one of the external connection terminals 60 is disposed by way of example. However, the auxiliary terminal 62 of the present invention is not limited to being disposed in the above-mentioned position but may also be disposed in various positions as needed. For example, the auxiliary terminal 62 may be disposed at a side at which the external connection terminals 60 are not disposed.

The second bobbin 30 according to the present embodiment is formed integrally with the first bobbin 20 as described above. To this end, the second bobbin 30 includes a fitting coupling part 40 formed on the outer peripheral edge of the flange part 33.

The fitting coupling part 40 includes respective fitting protrusions 28a and 38a and fitting grooves 28b and 38b provided in first and second bobbins 20 and 30 in a manner in which they are paired with each other.

The fitting protrusions 28a and 38a and the fitting grooves 28b and 38b are, respectively, formed on the outer peripheral edges of the flange parts 23 and 33 and are, respectively, formed at sides at which the first and second bobbins 20 and 30 contact each other.

The fitting protrusions 28a and 38a are formed on the outer peripheral edges of the flange parts 23 and 33 so as to protrude outwardly of the flange parts 23 and 33 in a form in which they extend from the flange part 23 and 33. These fitting protrusions 28a and 38a protrude from different positions at sides at which the flange parts 23 and 33 contact each other at the time of coupling the first and second bobbins 20 and 30.

The fitting grooves 28b and 38b are, respectively, formed on the outer peripheral edges of the flange parts 23 and 33 at positions in which the fitting protrusions 28a and 38a are fitted thereinto when the first and the second bobbins 20 and 30 are coupled with each other.

Therefore, when the first and second bobbins 20 and 30 are coupled with each other, the fitting protrusion 28a of the first bobbin 20 is fitted into the fitting groove 38b of the second bobbin 30, and the fitting protrusion 38a of the second bobbin 30 is fitted into the fitting groove 28b of the first bobbin 20.

The present embodiment describes a case in which all of the fitting protrusions 28a and 38a and fitting grooves 28b and 38b are formed in the ribs 27 and 37 of the flange parts 23 and 33 by way of example. In this case, since the fitting protrusions 28a and 38a and the fitting grooves 28b and 38b may have a size increased by a thickness of the ribs 27 and 37, the first and second bobbins 20 and 30 may be firmly coupled with each other.

However, the present invention is not limited thereto. The fitting coupling part 40 may also be formed directly at a side of the flange part 23 and 33 rather than the ribs 27 and 37. In addition, various applications maybe carried out. For example, a separate protruding block maybe formed on the flange part 23, and the fitting protrusions and the fitting grooves may be formed on the protruding block.

In addition, the present embodiment describes a case in which the fitting protrusions 28a and 38a protrude in a rectangular shape. However, the present invention is not limited thereto. In order to secure firmer adhesion, the fitting protrusions 28 and 38a may also have a hook shaped distal end. In this case, the fitting grooves 28b and 38b may further include a separate groove so that hook portions of the fitting protrusions 28a and 38a maybe fixed thereto while being hooked therein.

In addition, the present embodiment describes a case in which a single fitting protrusion 28a or 38a and a single fitting groove 28b or 38b are formed in each of the flange parts 23 and 33 by way of example. However, the present invention is not limited thereto. More fitting grooves 28b and 38b and fitting protrusions 28a and 38a may also be formed.

Through the fitting coupling part 40 configured as described above, the first and second bobbins 20 and 30 according to the present embodiment maybe easily coupled with each other, and may be not easily separated from each other after being coupled with each other.

Meanwhile, in the bobbin part 10 according to the present embodiment, when the first and second bobbins 20 and 30 are coupled with each other, the flange part 23 of the first bobbin 20 and the flange part 33 of the second bobbin 30 are positioned on the same plane. That is, the bobbin part 10 in which the first and second bobbins 20 and 30 are coupled with each other partially protrudes only at portions at which the insulating ribs 27 and 37 or the terminal connection parts 24 and 34 are formed and has an entirely flat thin shape. Therefore, the bobbin part may be easily used in thin display devices.

The individual bobbins 20 and 30 of the bobbin part 10 according to the present embodiment configured as described above may be easily manufactured by an injection molding method. However, the present invention is not limited thereto. The individual bobbins 20 and 30 may also be manufactured by various methods such as a press processing method, or the like. In addition, the individual bobbins 20 and 30 of the bobbin part 10 according to the present embodiment may be formed of an insulating resin material and a material having high heat resistance and high voltage resistance.

As a material of the individual bobbins 20 and 30, polyphenylenesulfide (PPS), liquid crystal polyester (LCP), polybutyleneterephthalate (PBT), polyethyleneterephthalate (PET), phenolic resin, and the like, may be used.

The coil part 70 may include the primary coil 70a and the secondary coil 70b.

The primary coil 70a is wound in the winding part 20a formed in the first bobbin 20.

In addition, as the primary coil 70a, a single strand of wire or a Ritz wire formed by twisting several strands may be used.

The lead wire of the primary coil 70a is connected to the external connection terminal 60 included in the first bobbin 20.

The secondary coil 70b maybe wound in the winding part 30a formed in the second bobbin 30, and the lead wire of the secondary coil 70b is connected to the external connection terminal 60 included in the second bobbin 30.

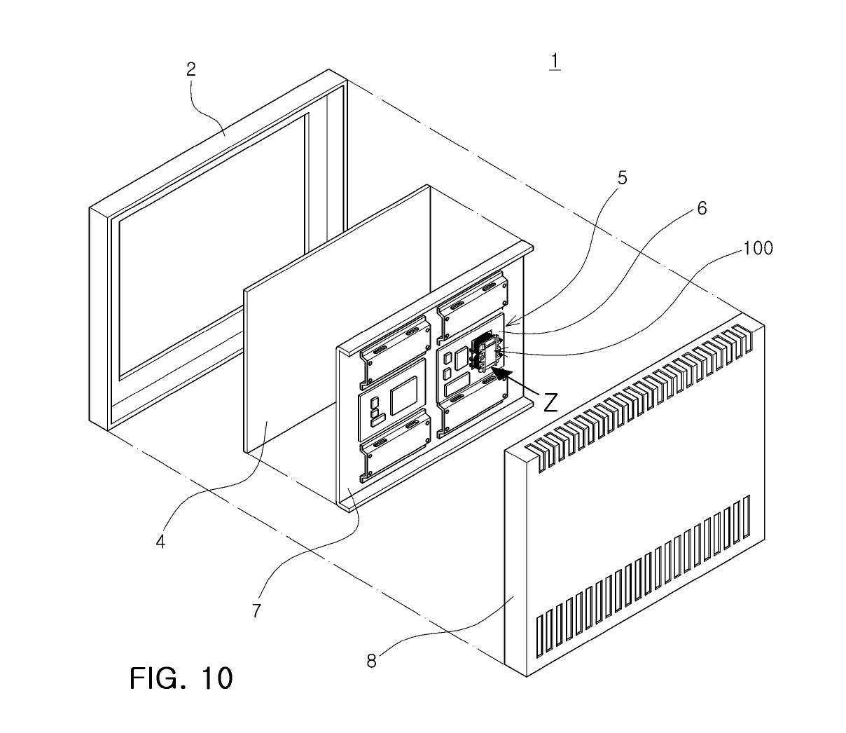

Both of the primary and secondary coils 70a and 70b according to the present embodiment are wound parallel with a substrate 6 (See FIG. 10) having the line filter 100 mounted thereon by the structure of the bobbins 20 and 30 in which they are wound.

In addition, in the line filter 100 according to the present embodiment, the primary and secondary coils 70a and 70b are wound in different directions (that is, opposite directions to each other). For example, when the primary coil is wound clockwise A (See FIG. 1) in the first bobbin 20, the secondary coil is wound counterclockwise B (See FIG. 1), and vice versa.

The core 80 is inserted into the through-holes 21 and 31 respectively formed in the inner portions of the first and second bobbins 20 and 30. The core 80 according to the present embodiment is configured in pairs. The pair of cores 80 may be inserted into the through-holes 21 and 31 of the first and second bobbins 20 and 30, respectively, to thereby be connected to each other while facing each other. As the core 80, a ‘UU’ shaped core and a ‘UI’ shaped core may be used.

The core 80 may be formed of Mn—Zn based ferrite having higher permeability, lower loss, higher saturation magnetic flux density, higher stability, and lower production costs, as compared to other materials. However, in the embodiment of the present invention, a shape or a material of the core 80 is not limited.

The line filter 100 according to the present embodiment as described above is configured to be appropriate for an automated manufacturing method.

That is, the coil 70 is separately wound in each of the first and second bobbins 20 and 30, the first and second bobbins 20 and 30 are coupled with each other, and the core 80 is then coupled thereto, such that the line filter 100 according to the present embodiment is completed.

To this end, in the line filter 100 according to the present embodiment, the coil 70 maybe wound in a state in which the first and second bobbins 20 and 30 are separated from each other so that the primary and secondary coils 70a and 70b may be automatically wound easily, as described above. Here, the coils may be wound by a separate automatic winding device.

Then, the first and second bobbins 20 and 30 in which the winding is completed are easily coupled with each other through the fitting coupling part 40. This process maybe also automatically performed through a separate device.

As described above, most of processes of manufacturing the line filter 100 according to the present invention may be automated. Therefore, costs and time required for manufacturing the line filter 100 may be significantly reduced.

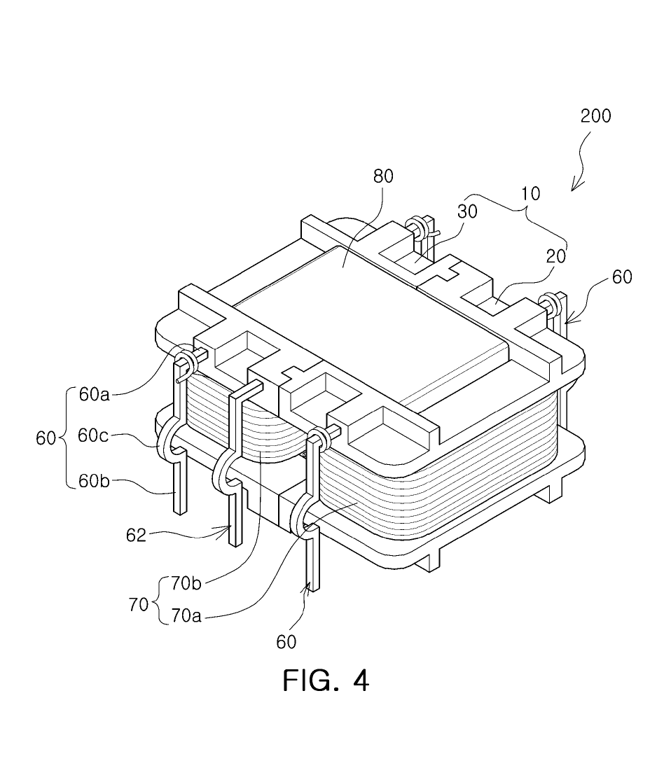

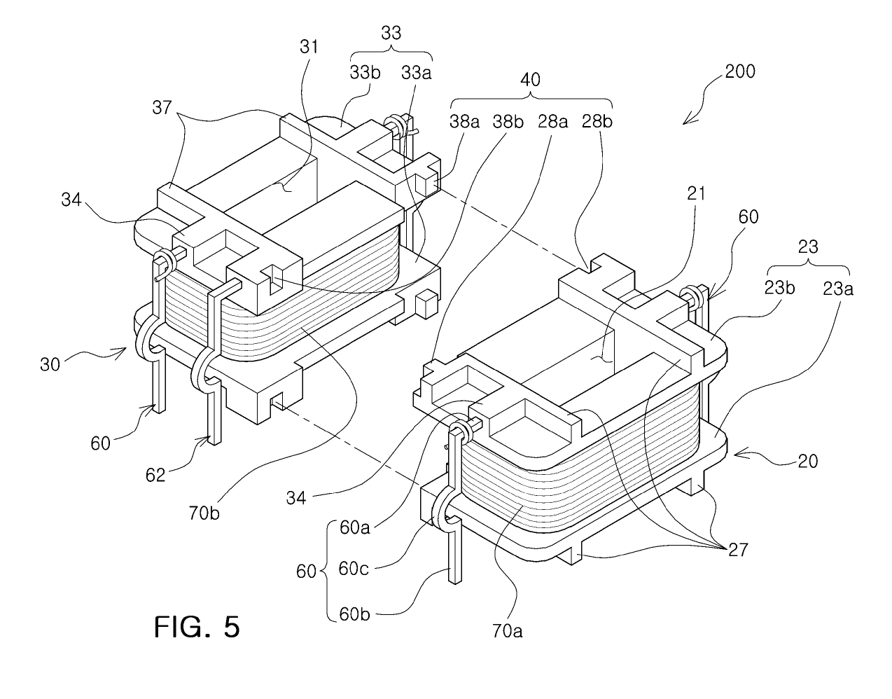

FIG. 4 is a perspective view schematically showing a line filter according to another embodiment of the present invention; and FIG. 5 is a perspective view showing separated bobbin parts of the line filter shown in FIG. 4.

Referring to FIGS. 4 and 5, a line filter 200 according to the present embodiment has a configuration similar to that of the line filter 100 (See FIG. 1) according to the above-mentioned embodiment with the exception of configurations of external connection terminals 60 of the first and second bobbins 20 and 30. Therefore, a detailed description of components configured identically to these of the above-mentioned embodiment will be omitted, and a configuration of the external connection terminals 60 will be mainly described.

Meanwhile, a flange part disposed at an upper portion of the line filter 200 may be called a first flange part in describing the present embodiment. However, referring to FIG. 4, the line filter 200 according to the present embodiment has a shape overturned from the shape of the above-mentioned line filter 100 by 180 degrees. Therefore, in consideration of consistency with the above-mentioned embodiment, the same terms and the same reference numerals will be used to describe the same components as those of the above-mentioned line filter 100.

That is, a flange part disposed at the upper portion of the line filter 200 will be designated as a second flange part, and a flange part disposed at a lower portion thereof will be designated as a first flange part.

The external connection terminals 60 of the line filter 200 according to the present embodiment protrude from the terminal connection part 24 and 34 of the second flange parts 23b and 33b; however, they are different from the external connection terminals 60 of the line filter 100 in that the coupling part 60b thereof is bent toward the first flange parts 23a and 33a rather than toward the outside of the line filter 100.

That is, the line filter 200 according to the present embodiment was derived in order to mount the line filter 100 (See FIG. 1) according to the above-mentioned embodiment on a substrate, or the like, in a state in which the line filter 100 is overturned. Therefore, the coupling parts 60b of the external connection terminals 60 according to the present embodiment have a length larger than the entire thickness of the line filter 200.

In addition, the external connection terminal 60 of the line filter 200 according to the present embodiment includes a protrusion part 60c formed in the coupling part 60b.

The protrusion part 60c protrudes from the coupling part 60b by a predetermined distance. This protrusion part 60c is provided in order to maintain a mounting height when the line filter 200 according to the present embodiment is mounted on the substrate.

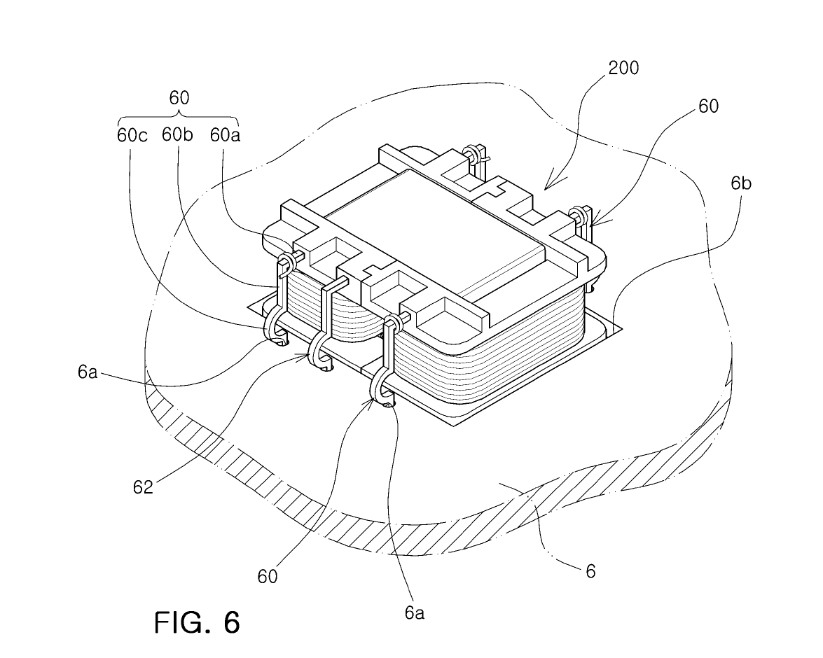

FIG. 6 is a perspective view showing a state in which the line filter of FIG. 4 is mounted on a substrate. Referring to FIGS. 4 through 6, the line filter 200 according to the present embodiment is seated on a substrate 6 while having the external connection terminals 60 inserted into coupling holes 6a formed in the substrate 6.

Here, the protrusion parts 60c of the external connection terminals 60 are caught on the substrate 6 without being inserted into the coupling holes 6a of the substrate 6, such that the line filter 200 is seated on the substrate 6, whereby the line filter 200 no longer moves downwardly with respect to the substrate 6.

In addition, the substrate 6 according to the present embodiment may include a through-hole 6b having a shape corresponding to a shape of the line filter 200. As shown in FIG. 6, when the through-hole 6b is formed in the substrate 6, the line filter 200 may be mounted on the substrate 6 in a state in which it is received in the through-hole 6b.

In this case, it is difficult to adjust a mounting height of the line filter 200. However, in the case of the line filter 200 according to the present embodiment, a mounting height may be set using the protrusion part 60c. That is, the protrusion part 60c is formed at a specific position at the time of manufacturing the external connection terminal 60, whereby the mounting height of the line filter 200 may be easily adjusted.

When the through-hole 6b is formed in the substrate 6, and the line filter 200 is mounted on the substrate 6 while being inserted into the through-hole 6b, the entire height of the SMPS in which the line filter 200 is mounted may be reduced, and the overall thickness of a display device in which the SMPS is mounted may be significantly reduced.

The line filter 200 according to the present embodiment, configured as described above, maybe easily formed by bending the external connection terminal 60.

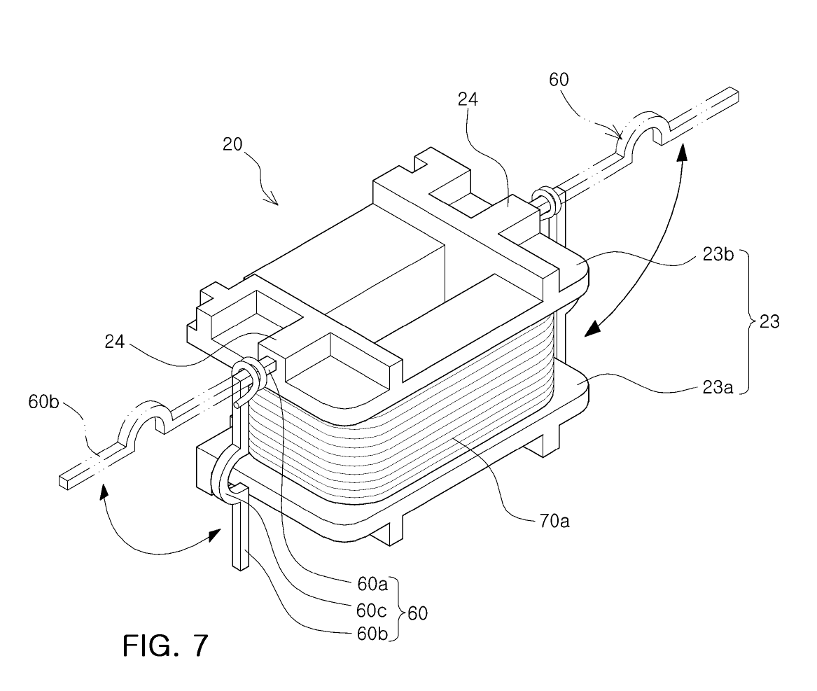

FIG. 7 is a perspective view showing a method of manufacturing the line filter of FIG. 4.

Referring to FIGS. 4 through 7, in a method of manufacturing the line filter 200 according to the present embodiment, the coil 70a is first wound in the bobbins 20 and 30 in a state in which the external connection terminal 60 is formed to be parallel with the second flange part 23b. Here, FIG. 7 shows only the first bobbin 20. However, the present embodiment is not limited thereto and may be applied equally to the second bobbin 30 (not shown in FIG. 7).

After the coil 70a is wound, a process of bending the external connection terminal 60 is performed. Here, the external connection terminals 60 are bent toward to the first flanges parts 23a and 33a rather than toward the outside of the line filter 100 as described above. Therefore, the external connection terminal 60 is divided into the extension part 60a and the coupling part 60b.

Meanwhile, the present embodiment describes a case in which the external connection terminal 60 includes the protrusion part 60c formed in a semicircular manner from the coupling part 60b by way of example. However, the present invention is not limited thereto. The external connection terminal 60 may have various shapes as long as it protrudes in a form in which it does not pass through the coupling hole 6a of the substrate 6.

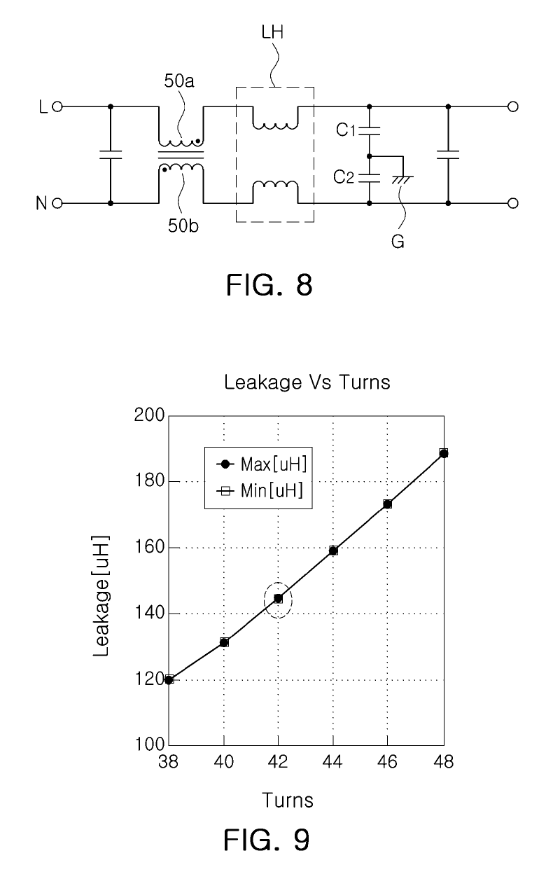

FIG. 8 is a circuit diagram of the line filter shown in FIG. 1; and FIG. 9 is a graph showing electrical characteristics of the line filter shown in FIG. 1.

First referring to FIG. 8, the line filter 100 according to the present embodiment may remove electromagnetic interference between power input terminals L and N and a rear end circuit (not shown, and for example, a rectifying circuit or the like). Here, the primary coil 50a of the line filter 100 may have one end connected to a live terminal L of the power input terminals and the other end connected to the rear end circuit. In addition, the secondary coil 50b may have one end connected to a neutral terminal N and the other end connected to the rear end circuit.

The primary and secondary coils 50a and 50b are formed between power paths through which a power is transferred between the power input terminals L and N and the rear end circuit as described above, whereby EMI, particularly, common mode EMI, generated between the power input terminals L and N and the rear end circuit, may be removed.

Meanwhile, referring to FIG. 8, first and second capacitors C1 and C2, which are Y-capacitors (Y-CAP) , include a first capacitor C1 connected between the primary coil 50a and a ground G and a second capacitor C2 connected between the ground G and the secondary coil 50b. These first and second capacitors C1 and C2 may be connected between the ground G and power supply to thereby remove the common mode EMI together with the line filter 100 according to the present embodiment.

In addition, in the line filter 100 according to the present embodiment, the primary and secondary coils 70a and 70b are wound in different directions (that is, opposite directions to each other) , as described above. The primary and secondary coils 50a and 50b are wound in opposite directions to each other as described above, such that leakage inductance LH is generated between the primary and secondary coils 50a and 50b electromagnetically coupled with each other. According to the embodiment of the present invention, differential mode EMI is removed using the leakage inductance.

Here, an amount of generated leakage inductance LH may be controlled by adjusting a length of the core 80, that is, a distance between the primary and secondary coils 70a and 70b.

Therefore, the line filter 100 according to the present embodiment may easily remove differential mode EMI without using a separate inductor element by using the leakage inductance LH generated by a degree of coupling between the primary coil 50a and the secondary coil 50b electromagnetically coupled thereto.

It may be appreciated from FIG. 9 that the leakage inductance generated by the line filter 100 according to the present embodiment as described above increases by enough to remove differential mode EMI, and that when the turns increase, leakage inductance further increases.

Meanwhile, the above-mentioned common mode and differential mode EMIs may also be removed by the line filter 200 shown in FIG. 4.

FIG. 10 is an exploded perspective view schematically showing a flat panel display device according to an embodiment of the present invention.

First referring to FIG. 10, a flat panel display device 1 according to an embodiment of the present invention may include a display panel 4, a SMPS 5 having the line filter 100 mounted therein, and covers 2 and 8.

The cover may include a front cover 2 and a back cover 8 and may be coupled with each other to thereby form a space therebetween.

The display panel 4 is disposed in an internal space formed by the covers 2 and 8. As the display panel, various flat panel display panels such as a liquid crystal display (LCD), a plasma display panel (PDP), an organic light emitting diode (OLED), and the like, may be used.

The SMPS 5 provides power to the display panel 4. The SMPS 5 may include a plurality of electronic components mounted on a substrate 6 (for example, a Printed Circuit Board (PCB)) thereof and particularly, may include at least one of the line filters 100 and 200 according to the above-mentioned embodiments mounted therein.

The SMPS 5 may be fixed to a chassis 7, and be disposed and fixed in the internal space formed by the covers 2 and 8 together with the display panel 4.

Here, in the line filter 100 mounted in the SMPS 5, the coil 50 (See FIG. 1) is wound parallel with the printed circuit board 6. In addition, when viewed from a plane of the printed circuit board 6 (a Z direction) , the coil 70 is wound clockwise or counterclockwise.

As set forth above, the line filter according to the embodiment of the present invention has a structure including a plurality of individually divided bobbins (for example, the first and second bobbins), the bobbins being coupled with each other. Therefore, an integral line filter may be completed by winding the coils in the individual bobbins, respectively, and then coupling the individual bobbins to each other. As a result, a process of producing the line filter may be automated.

In addition, in the case of the line filter according to the embodiment of the present invention, the common mode EMI may be filtered, and two coils are wound in opposite directions to each other, such that differential mode EMI may also be filtered using the leakage inductance generated between the two coils. Therefore, a circuit area may be significantly reduced, and manufacturing costs may be reduced.

In addition, when the line filter according to the embodiment of the present invention is mounted on the substrate, the coil of the line filter is maintained in a state in which it is wound in parallel with the substrate. When the coil is wound in parallel with the substrate as described above, interference between leakage magnetic flux generated from the line filter and the outside may be significantly reduced.

Therefore, even though the line filter is mounted in the thin display device, the generation of interference between the magnetic flux generated from the line filter and the back cover of the display device may be significantly reduced. Therefore, a phenomenon in which noise is generated in the display device by the line filter may be prevented. Therefore, the line filter may be easily used in thin display devices.

Meanwhile, the line filter according to the embodiments of the present invention as described above is not limited to the above-mentioned embodiments but maybe variously applied. For example, although the above-mentioned embodiments describe a case in which adhesion between the first and second bobbins is secured using the fitting protrusion and the fitting groove, the present invention is not limited thereto. That is, various configurations may be applied as long as adhesion between the first and second bobbins may be secured. For example, the first and second bobbins may be coupled with each other through a separate coupling member such as adhesive tape, a bracket, or the like.

In addition, the above-mentioned embodiments describe a case in which the bobbin has a generally rectangular shape. However, the present invention is not limited thereto. The bobbin may have various shapes such as a circular shape, an ellipse shape, or the like, as long as a desired function may be performed.

In addition, the above-mentioned embodiments describe a case in which the auxiliary terminal is provided in the second bobbin by way of example. However, the present invention is not limited thereto. The auxiliary terminal may be formed in various shapes in various positions as long as the first and second bobbins may be easily distinguished from each other. For example, the auxiliary terminal may be provided in the first bobbin.

Furthermore, although the embodiments of the present invention describe the line filter used in the display device by way of example, they are not limited thereto but may also be widely applied to other electronic devices as well as the line filter as long as the first and second coils are provided.

While the present invention has been shown and described in connection with the embodiments, it will be apparent to those skilled in the art that modifications and variations can be made without departing from the spirit and scope of the invention as defined by the appended claims.

What is claimed is:

1. A line filter comprising:
first and second bobbins each including a pipe shaped body part having a through-hole formed therein and a flange part protruding outwardly from both ends of the body part;
a core inserted into the through-hole to thereby form a magnetic path; and
a coil part including coils, each wound in the first and second bobbins,
one of the first and second bobbins having a coil wound clockwise therearound and the other thereof having a coil wound counterclockwise therearound.

2. The line filter of claim 1, wherein each of the first and second bobbins includes a fitting coupling part coupling the first and second bobbins to each other so that the flange part of the first bobbin and the flange part of the second bobbin contact each other.

3. The line filter of claim 2, wherein the fitting coupling part includes:
at least one fitting protrusion; and
at least one fitting groove having at least one fitting protrusion fitted thereinto.

4. The line filter of claim 3, wherein the fitting coupling part is formed on each surface on which the flange parts of the first bobbin and the flange parts of the second bobbin contact each other.

5. The line filter of claim 3, wherein the first and second bobbins are coupled with each other while the at least one fitting protrusion included in one of the first and second bobbins is fitted into the at least one fitting groove included in the other thereof.

6. The line filter of claim 1, wherein each of the first and second bobbins includes at least two external connection terminals.

7. The line filter of claim 6, wherein any one of the first and second bobbins further includes an auxiliary terminal having the same shape as that of the external connection terminal.

8. The line filter of claim 7, wherein the first and second bobbins are distinguished from each other by the auxiliary terminal.

9. The line filter of claim 6, wherein the external connection terminal includes:
an extension part extended from a first flange part formed at one end of the body part; and
a coupling part bent from the extension part and extended in a formation direction of a second flange part from the first flange part.

10. The line filter of claim 9, wherein after the coils are wound in the first and second bobbins, the external connection terminal is bent to thereby be divided into the extension part and the coupling part.

11. The line filter of claim 9, wherein when the line filter is mounted on an external substrate, the external connection terminal includes a protrusion part protruding outwardly from the coupling part, the protrusion part setting a mounting height of the line filter.

12. The line filter of claim 1, wherein each of the first and second bobbins includes at least one rib protruding from an outer surface of the flange part, the at least one rib reinforcing rigidity of the flange part.

13. The line filter of claim 1, wherein the core is a UU shaped core or a UI shaped core.

14. A line filter comprising:
first and second bobbins each including a pipe shaped body part having a through-hole formed therein and a flange part protruding outwardly from both ends of the body part;
a core inserted into the through-holes of the first and second bobbins to thereby form a magnetic path;
a coil part including coils, each wound in the first and second bobbins; and
a plurality of external connection terminals coupled to the first and second bobbins and electrically connected to the coils
one of the first and second bobbins further including an auxiliary terminal having the same shape as that of the external connection terminal.

15. The line filter of claim 14, wherein the first and second bobbins are coupled with each other so that flange parts of the first bobbin and flange parts of the second bobbin contact each other, such that they are formed integrally with each other.

16. The line filter of claim 15, further comprising fitting coupling parts each formed on a surface on which the flange parts of the first bobbin and the flange parts of the second bobbin contact each other to thereby couple the first and second bobbins to each other.

17. The line filter of claim 14, wherein a coil wound in one of the first and second bobbins is wound clockwise and a coil wound in the other thereof is wound counterclockwise.

18. A flat panel display device comprising:
a switching mode power supply including at least one line filter of claim 1 mounted on a substrate thereof;
a display panel receiving power from the switching mode power supply; and
covers protecting the display panel and the switching mode power supply.

19. The flat panel display device of claim 18, wherein the coils of the at least one line filter are wound in the first and second bobbins so as to be parallel with the substrate of the switching mode power supply.

20. The flat panel display device of claim 18, wherein the substrate of the switching mode power supply includes a through-hole formed therein, and the line filter is mounted on the substrate while being received in the through-hole.
